(19) United States
(12) Patent Application Publication
(10) Pub. No.: US 2006/0291288 A1
(43) Pub. Date: Dec. 28, 2006

(54) Flash memory device and read method

(76) Inventors: Joo-Ah Kang, Seoul (KR); Jong-hwa Kim, Hwaseong-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/347,224

(22) Filed: Feb. 6, 2006

(30) Foreign Application Priority Data
Jun. 23, 2005 (KR) 2005-54686

(51) Int. Cl. G11C 16/06

(52) U.S. Cl. 365/185.21

(57) ABSTRACT

In a flash memory device following precharge, a bitline and a sense node are coupled and then developed. A voltage apparent at the sense node is detected to recognize a data value of a corresponding memory cell. For a develop period, a bitline-side capacitance is much higher than a capacitance between adjacent sense nodes.

### BACKGROUND OF THE INVENTION

1. Field of the Invention

The embodiment of the invention relates to non-volatile memory devices. More particularly, embodiments of the invention relate to flash memory devices and a read method adapted for use with flash memory devices.

This application claims priority to Korean Patent Application No. 2005-54686 filed Jun. 23, 2005, the subject matter of which is hereby incorporated by reference.

2. Discussion of Related Art

Generally, semiconductor memory devices may be categorized as volatile memory devices or non-volatile memory devices. Volatile memory devices characteristically lose their data when power is interrupted. In contrast, non-volatile memory devices retain stored data even when power is interrupted, and are thus commonly used in devices and applications benefiting from this ability.

Volatile memory devices may be further classified into dynamic random access memories (DRAMs) and static random access memories (SRAMs).

Non-volatile memory devices include, as example, mask read-only memories (MROMs), programmable read-only memories (PROMs), erasable programmable read-only memories (EPROMs), and electrically erasable programmable read-only memories (EEPROMs).

Unfortunately, MROMs, PROMs, and EPROMs have difficulty in rewriting stored data because read and write operations cannot be freely conducted using commonly available electrical programming techniques. On the other hand, EEPROMs may be readily programmed and as such are increasingly used in systems requiring the continuous data update, such as auxiliary memory systems. Flash EEPROMs are a particularly advantageous type of EEPROM and are commonly used as a mass storage element within various systems because their integration density is higher than conventional EEPROMs. Among the flash EEPROM designs, the NAND-type flash EEPROM has a much higher integration density than the NOR-type or AND-type flash EEPROM.

In conventional form, a flash memory includes flash EEPROM cells each having a P-type semiconductor substrate, N-type source and drain regions, a channel region between the N-type source and drain regions, a floating gate adapted to store electrical charge, and a control gate disposed over the floating gate. The operation of the conventional flash memory device may be divided into three modes; commonly referred to as program, erase, and read.

In order to store data in a flash EEPROM cell, a program operation is performed following an erase operation. The erase operation is generally performed by applying 0 volts to the control gate while applying a high voltage (e.g., 20 volts) to the semiconductor substrate. Under such a voltage condition, the negative electrical charge accumulated on the floating gate is discharged to the substrate through a tunneling oxide using a conventionally understood F-N tunneling phenomenon. Thus, an effective threshold voltage (Vth) of the flash EEPROM cell transistor becomes negative, and the cell transistor is placed in a conductive state, (i.e., an “ON” state when a predetermined voltage (Vread) is applied to the control gate during a read operation (i.e., Vth<Vread)). At a state referred to as an erase state, the EEPROM cell may store logic “1” (or logic “0”).

In contrast, a program operation for a flash EEPROM cell is generally performed by applying a high voltage (e.g., 18 volts) to the control gate and while applying 0 volts to the semiconductor substrate including the source and drain. Under such voltage conditions, negative charge accumulates on the floating gate, again due to the F-N tunneling phenomenon. Thus, an effective threshold voltage (Vth) for the flash EEPROM cell becomes positive, and the cell transistor is placed in a nonconductive state, (i.e., an “OFF” state when the read voltage is applied to the control gate (i.e., Vth>Vread)). At a state referred to as a program state, the EEPROM cell will store logic values opposite to the logic value provided by the erase operation. Conventional program and erase operations for a flash memory device are disclosed, for example, in U. S. Pat. No. 5,841,721, the subject matter of which is hereby incorporated by reference.

To verify whether a flash memory cell is a programmed cell or an erased cell, a read operation is performed. The conventional read operation is conducted by applying the read voltage (Vread, typically around +4.5 volts) to unselected wordlines, while 0 volts are applied to selected wordlines. As is well understood by those skilled in the art, the conventional read operation is conducted using page buffers provided within the hardware structure of the flash memory device. One example of a page buffer is disclosed in U.S. Pat. No. 5,761,132, the subject matter of which is hereby incorporated by reference.

Before a read operation is conducted, a bitline is precharged. When the bitline is precharged, it is charged to a specific precharge level. After the bitline is precharged, the read voltage (Vread) is applied to unselected wordlines while 0 volts are applied to a selected wordline. If a memory cell connected with the selected wordline is an erased cell (i.e., an ON cell), the precharge level of the bitline “goes low”, that is, transitions to a low voltage level (e.g., ground). On the other hand, if the memory cell is a programmed cell (i.e., an OFF cell), the precharge level of the bitline is maintained. Thus, in this so-called “bitline develop” method, the precharge level of the bitline varies in accordance with the program state of a memory cell. Further, the time required to precharge the bitline to the desired voltage level is called “develop time”.

After the bitline develop is completed, a voltage at a related sense node is either maintained at the precharge level or it goes low. For example, if a bitline is maintained at the precharge level, a corresponding memory cell is detected as an OFF cell and the sense node is also maintained at the precharged level. On the other hand, if a bitline goes low, a corresponding memory cell is detected as an ON cell and the sense node is also discharged to a low level. Afterwards, a voltage level apparent at the sense node is latched into a latch circuit as a read result.

However, several problems arise with the foregoing read operation due to the presence of parasitic capacitances (hereafter denoted as CC0, CC1, CC2, etc.) between page buffers and sense nodes within the flash memory device. These problems will now be described in some additional detail.

Generally, a first sense node (e.g., SO0) corresponding to an OFF cell is maintained at a floating state during a sensing period. However, when a voltage at an adjacent second sense node (e.g., SO1) corresponding to an ON cell goes low, the voltage at the first sense node, which should be maintained at the floating state, is nonetheless affected by a parasitic capacitance CC0 between the adjacent first and second sense nodes (SO0 and SO1). If the magnitude of the parasitic capacitance CC0 is small, the voltage at the first sense node (SO0) will be scarcely affected and will generally be maintained at the precharge level of the bitline. On the other hand, if the magnitude of the parasitic capacitance CC0 is large, the voltage at the first sense node (SO0) may be materially affected and may drop to an extent that data integrity it threatened.

As described above, the voltage at the first sense node (SO0) corresponding to an OFF cell may drop with a voltage fluctuation occurring at an adjacent second sense node (SO1). This result is referred to as a “coupled down phenomenon.” Since the coupled down phenomenon may arise from either adjacent sense nodes located on both sides of a subject sense node, the coupled-down voltage at the subject sense node may be doubly influenced by parasitic capacitances between both adjacent sense nodes. If the voltage of the subject sense node drops below the trap voltage required to change a latched data value, a read error arises in which an OFF cell is actually detected as an ON cell.

Unfortunately, as the integration density of memory devices increases and design rules decrease accordingly, the potential magnitude of parasitic capacitances between sense nodes only increases. That is, as the integration density of memory devices increases, the sense nodes between adjacent pages buffers become increasingly susceptible to capacitive coupling effects which enhance the probability of a read error.

This is particularly true where discharge and sense operations applied to sense nodes are not conducted only after bitline develop has been completed. As a result, sense node voltages are maintained at a precharge level or discharged to a low level according to the result of the bitline develop, which is done at one time. Therefore, it is increasingly probable that the voltages at the sense nodes are affected by voltage fluctuations at adjacent sense nodes.

### SUMMARY OF THE INVENTION

Thus, in one embodiment, the invention provides a read method adapted for use with a flash memory device, comprising; precharging a bitline and a sense node, coupling the bitline and sense node, developing the bitline and the sense node while coupled, and detecting a voltage at the sense node to recognize a data value for a corresponding memory cell.

In another embodiment, the invention provides a flash memory device comprising; a memory cell array comprising a plurality of memory cells, each disposed at a respective intersection of a bitline and a wordline, and a page buffer circuit comprising a plurality of page buffers, each page buffer being adapted to sense data stored in a memory cell connected to a selected bitline and comprising; a precharge unit adapted to precharge a corresponding bitline and sense node, adapted to couple the bitline and sense node, and further adapted to develop the bitline and the sense node while coupled, and a sense and latch unit adapted to sense and latch a data value stored in the memory cell in response to a developed result at the sense node.

### BRIEF DESCRIPTION OF THE DRAWINGS

Several embodiments of the invention will be described with reference to the accompanying drawings. Throughout the drawings and associated written description like reference numerals indicate like or similar elements. In the drawings:

FIG. 1 is a block diagram of a flash memory device designed in accordance with one embodiment of the invention;

FIG. 2 is a circuit diagram further illustrating a page buffer circuit associated with the exemplary flash device shown in FIG. 1;

FIG. 3 is a timing diagram further illustrating the operation of the exemplary page buffer shown in FIGS. 1 and 2; and,

FIG. 4 is a flowchart generally illustrating a read method for a flash memory device designed in accordance with an embodiment of the present invention.

### DESCRIPTION OF EXEMPLARY EMBODIMENTS

Several embodiments of the invention will be described hereafter with reference to the accompanying drawings. The present invention may, however, be variously embodied in different forms and should not be constructed as being limited to only the described embodiments. Rather, the embodiments are provided as teaching example.

In a flash memory device according to the present invention, a bitline and a sense node are precharged. Further, the bitline and the sense node are developed while coupled. A voltage, as detected at a sense node, indicates a data value stored in a corresponding memory cell. Since a bitline-side capacitance has a much greater value than the capacitance associated with adjacent sense nodes during a develop period, the sense node voltage may be determined by a bitline voltage without being affected by a voltage fluctuation at an adjacent node. Thus, a more accurate and stable read result may be obtained.

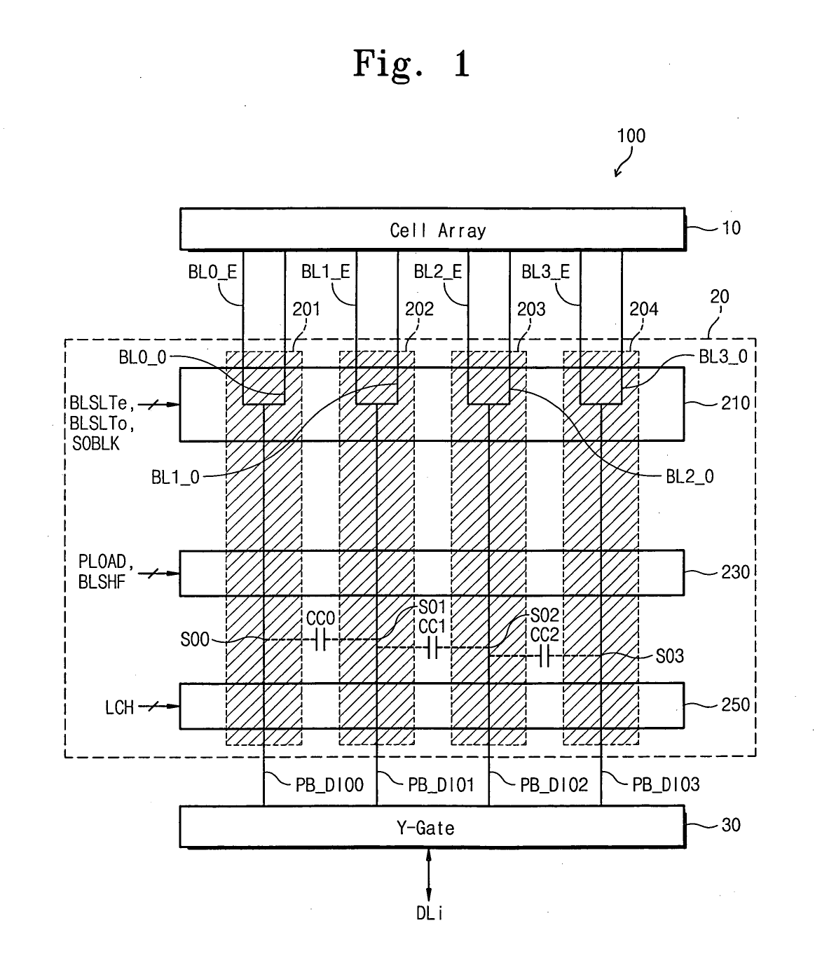

An exemplary flash memory device 100 is illustrated in FIG. 1, and comprises a memory cell array 10 adapted to store data. Although not shown in this figure, the memory cell array typically includes a plurality of cell string (or NAND strings) each being connected to corresponding bitlines. As is conventionally understood, each of the cell strings includes a string select transistor connected to a corresponding bitline, a ground select transistor connected to a common source line, and memory cells coupled serially between the string select transistor and the ground select transistor. A plurality of bitlines are connected within the memory cell array 10. In FIG. 1, only four bitline pairs (BL0_E, BL0_O), (BL1_E, BL1_O), (BL2_E, BL2_O), and (BL3_E, BL3_O) are shown among a plurality of bitline pairs.

Corresponding page buffers 201, 202, 203, and 204 are electrically connected with the respective bitline pairs. Each of the page buffers 201, 202, 203, and 204 acts as a sense amplifier during read/verify operations, and acts as a driver for driving a bitline in accordance with data to be programmed during a program operation. In that the buffer pages 201, 202, 203, and 204 have the same configuration, the configuration of only one page buffer (e.g., 201) will be described for the convenience. Accordingly, similar elements in page buffers 201-204 are designated by the analogous reference numerals. Data is input to and output from the page buffers 201, 202, 203, and 204 through a conventionally constructed Y-Gate circuit 30.

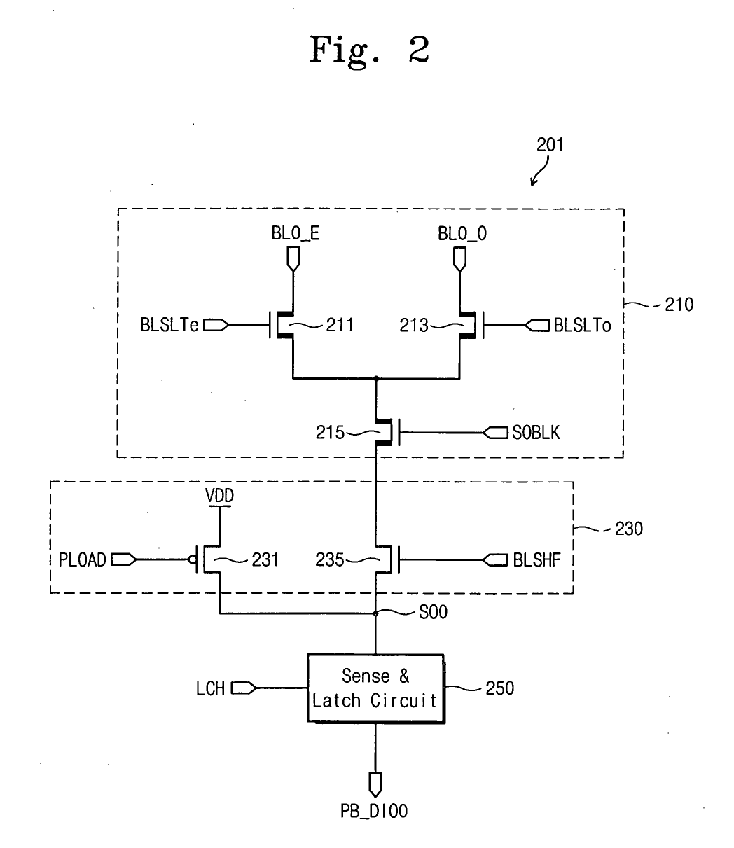

As illustrated in FIG. 2, the page buffer 201 comprises a bitline select and bias circuit 210, a precharge circuit 230, and a sense and latch circuit 250. A sense node (SO0) is provided between the precharge circuit 230 and latch circuit 250.

The bitline select and bias circuit 210 selects a bitline to be sensed, and the precharge circuit 230 precharges a bitline BL0_E and sense node SO0 before reading memory cells connected with a selected bitline. When both the bitline BL0_E and the sense node SO0 are precharged, a read voltage (Vread, e.g., +4.5V) is applied to an unselected wordline while a voltage of 0V is applied to a selected wordline. The precharge circuit 230 cuts off the supply of a precharge power to the bitline BL0_E and the sense node SO0. While a current path between the bitline BL0_E and the sense node SO0 is opened sufficiently, a bitline develop operation is conducted. This leads to the same effect as the bitline BL0_E and the sense node SO0 are shorted to each other while an external power supply is cut off. In this case, voltage levels of the bitline BL0_E and the sense node SO0 are nearly identically developed and data is recognized by sensing the voltage level of the sense node SO0 after bitline develop has been completed.

A voltage apparent at sense node SO0 slowly fluctuates with the develop state of the bitline BL0_E at a sufficient interval. Therefore, the voltage of the sense node SO0 is scarcely affected by the capacitance of an adjacent sense node. For example, even if the first sense node SO0 is affected by the capacitance of a second adjacent node, the capacitance between bitline BL0_E and sense node SO0 is much greater than the capacitance between the first and second sense nodes. Thus, degree to which this lesser capacitance affects the resulting voltage is substantially negligible. Namely, although adjacent nodes are coupled, voltage loss for an adjacent node is compensated due to a capacitance element between a bitline BL0_E and a sense node SO0. This makes it possible to advantageously prevent a sense node voltage drop caused by an ON cell adjacent to an OFF cell that should be maintained at a precharge level of a bitline. As a result, read errors arising from a capacitive coupling between adjacent nodes may be suppressed.

The sense and latch circuit 250 senses the voltage apparent at sense node SO0 as a read result and latches the sensed voltage. It should be noted that exemplary configurations of the bitline select circuit 210, precharge circuit 230, and sense and latch circuit 250 shown in FIG. 2 may be variously modified without departing from the scope of the present invention. Especially, the configuration and structure of the latch circuit 250, as adapted to sense and latch the voltage apparent at the sense node SO0, may be variously modified within the data input/output path. Since a read method for a flash memory device designed in accordance with an embodiment of the present invention may be applied to any sense and latch circuit, the sense and latch circuit 250 is not limited to the specific illustrated configuration.

However, for purposes of illustration, exemplary configurations for the bitline select circuit 210 and precharge circuit 230 will now be described in some additional detail.

The illustrated bitline select circuit 230 comprises first, second, and third NMOS transistors 211, 213, and 215. The first and second NMOS transistors 211 and 213 are connected with corresponding bitlines BL0_E and BL0_O, respectively. The first and second NMOS transistors 211 and 213 select corresponding bitlines in response to bitline select signals BLSLTe and BLSLTo applied to gates, respectively. A pair of bitlines BL0_E and BL0_O are configured to share a page buffer 201. A selected one of the bitlines BL0_E and BL0_O is electrically connected to the precharge circuit 230 and the sense and latch circuit 250. For the convenience of description, it is assumed that among the bitline pair BL0_E and BL0_O connected to a page buffer 201, an even-number bitline BL0_E is selected while an odd-number bitline BL0_O is unselected.

The third NMOS transistor 215 is coupled between the first NMOS transistor 211 and the precharge circuit 230 and between the second NMOS transistor 213 and the precharge circuit 230, preventing a higher voltage than a power supply voltage (Vdd) from being applied directly to the page buffer 201: As is well understood conventionally, the page buffer 201 may be a low voltage circuit operating at a power supply voltage (Vdd). Hence, when a voltage higher than the power supply voltage (Vdd) is directly applied to a low voltage circuit, such as a page buffer, low voltage transistors constituting the page buffer 201 may be broken down or destroyed. For this reason, the first, second, and third transistors 211, 213, and 215 included in the bitline select and bias circuit 210 are high voltage transistors adapted from use with high voltages. Each of the first, second, and third transistors 211, 213, and 215 is a high voltage transistor having a relatively high breakdown voltage of, for example, about 28 volts.

The exemplary precharge circuit 230 comprises a PMOS transistor 231 and an NMOS transistor 235, which are low voltage transistors each having a relatively low breakdown voltage of, for example, about 7 volts.

The PMOS transistors 231 is coupled between a power supply voltage (Vdd) and a sense node SO0 and controlled by a precharge control signal PLOAD. The NMOS transistor 235 is coupled between the third NMOS transistors 215 constructed in the bitline select and bias circuit 210 and the sense node SO0. A drain terminal of the NMOS transistor 235 is coupled to a sense node SO0, and a source terminal thereof is connected to a bitline BL0_E through the select circuit 210. A gate terminal of the NMOS transistor 235 is connected to a control circuit (not shown) to receive a shutoff control signal BLSHF. The NMOS transistor 235 electrically connects or insulates the bitline BL0_E to/from the sense node SO0. In view of the foregoing, the NMOS transistor 235 may be referred to as a shutoff transistor.

Depending upon whether the PMOS transistor 231 and the NMOS transistor 235 are turned ON/OFF, the bitline BL0_E and the sense node SO0 are precharged to a predetermined precharge level. For example, if both the PMOS transistor 231 and the NMOS transistor 235 are turned on, the bitline BL0_E and the sense node SO0 start to be precharged to a predetermined precharge level.

A precharge level of the bitline BL0_E is determined by a voltage level of a shutoff control signal BLSHF applied to the gate of the NMOS transistor 235 and a threshold voltage Vth of the NMOS transistor 235. When a shutoff signal BLSHF of a high level (e.g., 2 volts) is applied to the gate terminal of the NMOS transistor 235 and a power supply voltage Vdd is applied to the drain terminal (i.e., sense node SO0) of the NMOS transistor 235, the bitline BL0_E is precharged to a precharge level of BLSHF—Vth (BLSHF being a voltage level of the shutoff control signal, and Vth being a threshold voltage of the NMOS transistor 235).

After the bitline BL0_E is precharged to a predetermined precharge level, the PMOS transistor 231 of the precharge circuit 230 is turned OFF to cut off the supply of a power supply voltage to the bitline BL0_E and the sense node SO0. A read voltage (Vread) is applied to unselected wordlines and a voltage of 0 volts is applied to a selected wordline to conduct a read operation. Consequently, a bitline develop is started.

While a bitline is developed, the precharge circuit 230 controls the voltage of the sense node SO0 to be developed according to the voltage of the bitline BL0_E. In other words, the precharge circuit 230 controls the bitline BL0_E and the sense node SO0 in such a manner that they are developed simultaneously.

Specifically, a voltage (e.g., 4 volts) is applied to a gate terminal of the NMOS transistor 235 in the precharge circuit 230 for a develop period. The voltage (e.g., 4 volts) applied during the develop period is higher than a voltage (e.g., 2 volts) applied during the precharge period. As a result, a current flow rate between the bitline BL0_E and the sense node SO0 (or charge sharing ratio) increases. Thus, the voltage of the sense node SO0 may quickly reach the develop results of the bitline BL0_E. Namely, it may lead to the same effect as if the bitline BL0_E and the sense node SO0 were shorted together.

After development, voltages apparent at the sense node SO0 and the bitline BL0_E corresponding to an ON cell at a low level (e.g., 0.3 volt) while voltages apparent at sense node SO0 and the bitline BL0_E corresponding to an OFF cell are maintained at a precharge level (e.g., 1.0 volt). Since a develop result of the sense node SO0 is identical to that of the bitline BL0_E, it is recognized whether a corresponding memory cell is an ON cell or an OFF cell, based on the voltage level of the developed sense node SO0. Since the voltage of the sense node SO0 are slowly fluctuated with the developed state of the bitline BL0_E at a sufficient interval, the probability of coupling between adjacent nodes is lowered.

Although the voltage apparent at the sense node SO0 corresponding to an ON cell is lost by a parasitic capacitance existing between an adjacent node during the develop period, the voltage lost from the sense node SO0 is compensated for by the capacitance effect of connected bitline BL0_E. This is because a higher voltage (e.g., 4 volts) than a voltage (e.g., 2 volts) applied for a precharge period is continuously applied to the bitline BL0_E connected to the sense node SO0. Since the capacitance between bitline BL0_E and sense node SO0 is much higher than the capacitance between the adjacent nodes, the developed result at the sense node SO0 is not materially affected by the adjacent nodes.

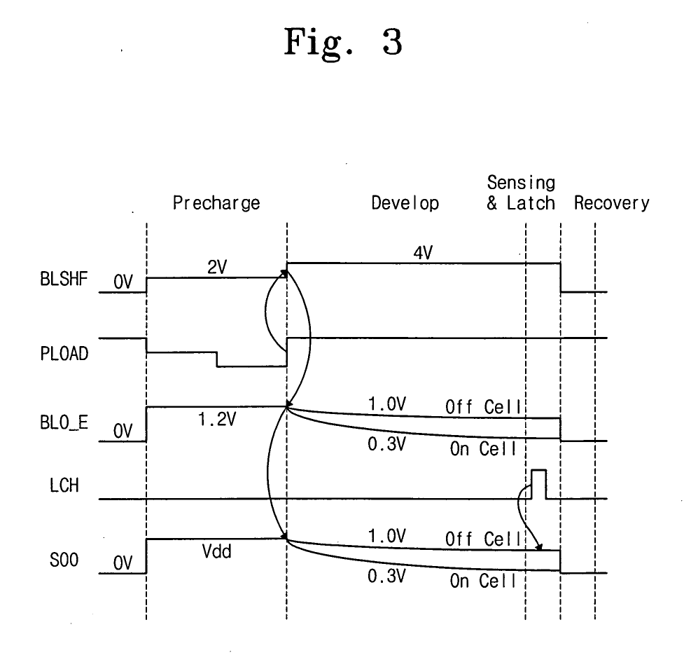

FIG. 3 is a timing diagram related to the exemplary page buffer 201 shown in FIGS. 1 and 2. Referring to FIGS. 2 and 3, an exemplary operation period for the page buffer 201 is divided into a precharge period, a develop period, and a sense & latch period, and a recovery period.

When the precharge period is started, a precharge control signal PLOAD applied to a PMOS transistor 231 transitions from a high level to a low level and a shutoff control signal BLSHF transitions from a low level to a high level. For this reason, both the PMOS transistors 231 and an NMOS transistors 235 constructed in a precharge circuit 230 are turned ON. As a result, both a sense node SO0 and a bitline BL0_E are precharged by a power supply voltage (Vdd).

In order to develop a bitline, a precharge control signal PLOAD transitioning from a low level to a high level is applied to a gate terminal of the PMOS transistor 231. As a result, supply of the power supply voltage (Vdd) to the sense node SO0 is cut off. At the same time, a shutoff control signal BLSHF having a higher voltage (e.g., 4 volts) than a voltage (e.g., 2 volts) applied for the precharge period is applied to a gate terminal of the NMOS transistor 235. As a result, the sense node SO0 is coupled with the bitline BL0_E to rapidly fluctuate the voltage of the sense node with the voltage of the bitline BL0_E. Since a capacitance between the bitline BL0_E and the sense node SO0 is much higher than a capacitance between the adjacent nodes, the developed result at the sense node SO0 is not materially affected by the capacitance between the adjacent nodes.

After the development, voltages of the sense node SO0 and the bitline BL0_E corresponding to an ON cell is reduced to a low level (e.g., 0.3 volt) while voltages of the sense node SO0 and the bitline BL0_E corresponding to an OFF cell are maintained at a precharge level (e.g., 1.0 volt). When a latch signal is applied for commanding the developed result of the sense node SO0 to be sensed and latched, a voltage of the developed sense node SO0 is sensed and latched.

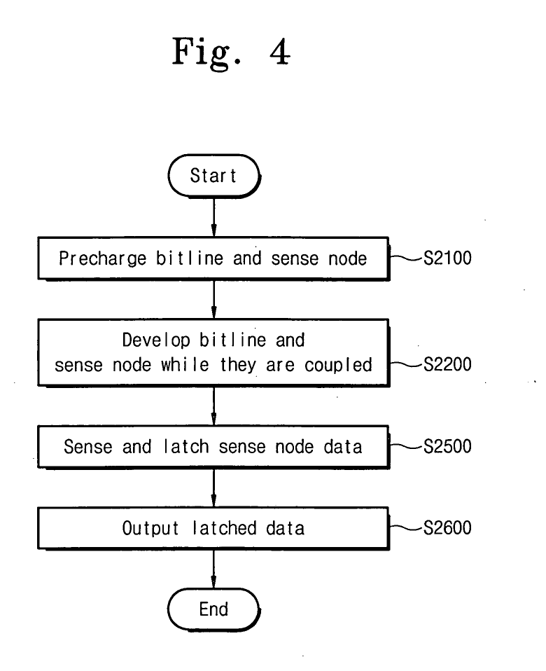

An exemplary read operation for a flash memory device according to an embodiment of the invention will now be described below with reference to FIG. 4.

As illustrated in FIG. 4, a bitline BL0_E and a sense node SO0 are precharged (S2100). The bitline BL0_E and the sense node SO0 are developed while they are coupled (S2200).

The precharge and develop operations are controlled by a precharge circuit (230 of FIG. 2). At S2200, the precharge circuit 230 cuts off a power supply voltage applied to the bitline BL0_E and the sense node SO0 and sufficiently opens a current path between the bitline BL0_E and the sense node SO0 to couple the sense node SO0 with the bitline BL0_E. Voltages of the bitline BL0_E and the sense node SO0 are similarly fluctuated. The voltage of the sense node SO0 is developed at a sufficient interval while the bitline BL0_E is developed. Since the capacitance between the bitline BL0_E and the sense node SO0 is much higher than the capacitance between adjacent nodes, the voltage of the sense node SO0 is affected only by the voltage of the bitline BL0_E, not by the adjacent node.

The voltage of the developed sense node SO0 is sensed and the sensed result is latched (S2500). The data latched at S2500 is output as read data (S2600).

As explained so far, after a bitline and a sense node are precharged, they are developed while they are coupled. A voltage of the sense node is detected to recognize a data value of a corresponding memory cell. For a develop period, a bitline-side capacitance is much higher than a capacitance between adjacent sense nodes. Therefore, the voltage of the sense node can be decided by a voltage of the bitline without being affected by the adjacent nodes. In other words, a page buffer can be designed irrespective of a parasitic capacitance between sense nodes. Therefore, it is possible to simplify the design and reduce the size of an integrated circuit containing the page buffer.

While the present invention has been described with reference to several embodiments, those skilled in the art will recognize that modifications and changes may be made in form and detail without departing from the scope of the invention as defined by the following claims.

What is claimed is:

1. A read method adapted for use with a flash memory device, comprising:
precharging a bitline and a sense node;
coupling the bitline and sense node;
developing the bitline and the sense node while coupled; and
detecting a voltage at the sense node to recognize a data value for a corresponding memory cell.

2. The read method of claim 1, wherein the sense node is developed while the bitline is developed.

3. The read method of claim 1, wherein the sense node has a develop result corresponding to a develop result on the bitline.

4. The read method of claim 1, wherein precharging the bitline and the sense node comprises applying a first voltage to the bitline and the sense node.

5. The read method of claim 4, wherein developing the bitline and the sense node comprises:
cutting off the first voltage; and,
applying a second voltage, higher than the first voltage, to the bitline.

6. The read method of claim 1, wherein upon developing the bitline and the sense node a capacitance between the bitline and the sense node is higher than a capacitance between the sense node and an adjacent sense node.

7. A flash memory device comprising:
a memory cell array comprising a plurality of memory cells, each disposed at a respective intersection of a bitline and a wordline; and
a page buffer circuit comprising a plurality of page buffers, each page buffer being adapted to sense data stored in a memory cell connected to a selected bitline and comprising:
a precharge unit adapted to precharge a corresponding bitline and sense node, adapted to couple the bitline and sense node, and further adapted to develop the bitline and the sense node while coupled; and
a sense and latch unit adapted to sense and latch a data value stored in the memory cell in response to a developed result at the sense node.

8. The flash memory device of claim 7, wherein the precharge unit comprises:
a first transistor adapted to supply a precharge voltage to the sense node and the bitline in response to a first control signal; and
a second transistor adapted to control a precharge level on the bitline in response to a second control signal, having a higher voltage than the first control signal.

9. The flash memory device of claim 8, wherein the precharge level of the bitline is equal to a value obtained by subtracting a threshold voltage value of the second transistor from a voltage level of the second control signal.

10. The flash memory device of claim 8, wherein the precharge unit is further adapted to cut off the precharge voltage by means of the first transistor after the bitline and the sense node are precharged and in response to the first control signal.

11. The flash memory device of claim 9, wherein the precharge unit is further adapted to match voltage levels between the bitline and the sense node in response to the second control signal after the bitline and the sense node are precharged.

12. The flash memory device of claim 11, wherein the sense node has a developed result corresponding to the developed result of the bitline.

13. The flash memory device of claim 11, wherein a capacitance between the bitline and the sense node is higher than a capacitance between the sense node and an adjacent node following development.
